(19) United States
(12) Patent Application Publication
(10) Pub. No.: US 2022/0006043 A1
(43) Pub. Date: Jan. 6, 2022

(54) DISPLAY MODULE, METHOD FOR FABRICATING SAME, AND DISPLAY PANEL

(71) Applicant: WUHAN CHINA STAR OPTOELECTRONICS SEMICONDUCTOR DISPLAY TECHNOLOGY CO., LTD, Wuhan (CN)

(72) Inventor: Shuang E, Wuhan (CN)

(21) Appl. No.: 16/640,377

(22) PCT Filed: Jan. 9, 2020
(86) PCT No.: PCT/CN2020/071043

§ 371 Date: Feb. 20, 2020

(30) Foreign Application Priority Data
Jul. 8, 2019 (CN) 201910612022.6

(51) Int. Cl. H01L 51/52

(52) U.S. Cl. CPC H01L 51/5237; H01L 27/3244

(57) ABSTRACT

The present disclosure provides a display module, a method for fabricating the same, and a display panel comprising the same. The display module comprises a flexible display panel and a support film. The flexible display panel comprises a display area and a non-display area. The support film comprises a first support film disposed below the display area, and a second support film disposed below the non-display area and composed of a cured organic material. Because the organic material has good fluidity and adhesiveness, gas between the flexible display panel and the second support film can be effectively discharged. This prevents air bubbles from being generated between the flexible display panel and the second support film.

The present application claims priority to Chinese Patent Application No. 201910612022.6, titled “DISPLAY MODULE, METHOD FOR FABRICATING SAME, AND DISPLAY PANEL”, filed on Jul. 8, 2019, the content of which is incorporated into the present disclosure in its entirety.

### FIELD OF INVENTION

The present disclosure relates to the technical field of display, and particularly to a display module, a method for fabricating the same, and a display panel comprising the same.

### BACKGROUND

In a current flexible display device, after a glass substrate is peeled off from a flexible substrate, the flexible substrate becomes very soft. In order to better protect the flexible substrate in subsequent processes, a support film with a certain rigidity must be adhered to the flexible substrate to protect and support the flexible substrate.

However, due to a difference between a film structure in a display area of a flexible display panel and a film structure in a non-display area of the flexible display panel, the non-display area of the display panel cannot be well supported during adhesion of the support film. This causes air bubbles to be generated between the flexible substrate and the support film, thereby affecting product performance of the display device.

Therefore, a current display module has a problem that there are air bubbles between a flexible substrate and a support film, which needs to be solved.

### SUMMARY OF DISCLOSURE

The present disclosure provides a display module, a method for fabricating the same, and a display panel comprising the same to solve the problem that there are air bubbles between a flexible substrate and a support film in a current display module.

In order to solve the above problem, the present disclosure provides the following technical solutions.

The present disclosure provides a display module comprising:
a flexible display panel; and
a support film configured to support the flexible display panel and comprising:
   a first support film disposed below a display area; and
   a second support film disposed below a non-display area and composed of a cured organic material.

In an embodiment of the display module, the organic material is a hydrogel.

In an embodiment of the display module, the hydrogel is a UV-curable hydrogel or a thermosetting hydrogel.

In an embodiment of the display module, the hydrogel comprises one or more of acrylic resin, urethane resin, and epoxy resin.

In an embodiment of the display module, the second support film is directly connected to the first support film.

In an embodiment of the display module, there is an interval between the second support film and the first support film, and there is no support film in a region of the interval.

In an embodiment of the display module, the region of the interval corresponds to a bending area of the flexible display panel.

In an embodiment of the display module, thickness of the second support film is less than thickness of the first support film.

In an embodiment of the display module, thickness of the second support film is same as thickness of the first support film.

In an embodiment of the display module, thickness of the second support film is greater than thickness of the first support film.

The present disclosure further provides a display device comprising a display module. The display module comprises a flexible display panel and a support film configured to support the flexible display panel. The support film comprises a first support film disposed below a display area, and a second support film disposed below a non-display area and composed of a cured organic material.

In an embodiment of the display device, the organic material is a hydrogel.

In an embodiment of the display device, the hydrogel is a UV-curable hydrogel or a thermosetting hydrogel.

In an embodiment of the display device, the hydrogel comprises one or more of acrylic resin, urethane resin, and epoxy resin.

In an embodiment of the display device, the second support film is directly connected to the first support film.

In an embodiment of the display device, there is an interval between the second support film and the first support film, and there is no support film in a region of the interval.

In an embodiment of the display device, the region of the interval corresponds to a bending area of the flexible display panel.

In an embodiment of the display device, thickness of the second support film is less than thickness of the first support film.

In an embodiment of the display device, thickness of the second support film is same as thickness of the first support film.

The present disclosure further provides a method for fabricating a display module. The method comprises:
providing a flexible display panel;
adhering a first support film to a surface of the flexible substrate away from the film structure in the display area of the flexible display panel; and
adhering a second support film to a surface of the flexible substrate away from the film structure in the non-display area of the flexible display panel.

The present disclosure provides a display module, a method for fabricating the same, and a display panel comprising the same. The display module comprises a flexible display panel, a first support film disposed in a display area, and a second support film disposed in a non-display area. The second support film is composed of a cured organic material. The second support film composed of the cured organic material is adhered below a flexible substrate in a non-display area. Because the organic material has good fluidity and adhesiveness, no additional air bubble removal operation is needed. Gas between the flexible substrate and the second support film can be effectively discharged during processes of adhering and curing. This prevents air bubbles from being generated between the flexible substrate and the support film due to a structure of the non-display area. Furthermore, a color of a hydrogel changes according to a viscosity of the hydrogel. This property can be used to determine and control whether the viscosity of the hydrogel conforms to a design, so as to prepare a second support film with a high yield and reduce a risk of the second support film peeling off from the flexible substrate.

### BRIEF DESCRIPTION OF DRAWINGS

FIG. 1 is a schematic structural diagram of a display module according to an embodiment of the present disclosure.

FIG. 2 (a) is a schematic diagram of a first structure of a display module according to an embodiment of the present disclosure.

FIG. 2 (b) is a schematic diagram of a second structure of a display module according to an embodiment of the present disclosure.

FIG. 2 (c) is a schematic diagram of a third structure of a display module according to an embodiment of the present disclosure.

FIG. 3 (a) is a schematic diagram of a fourth structure of a display module according to an embodiment of the present disclosure.

FIG. 3 (b) is a schematic diagram of a fifth structure of a display module according to an embodiment of the present disclosure.

FIG. 3 (c) is a schematic diagram of a sixth structure of a display module according to an embodiment of the present disclosure.

FIG. 4 is a schematic structural diagram of a display device according to an embodiment of the present disclosure.

FIG. 5 is a flowchart of a method for fabricating a display module according to an embodiment of the present disclosure.

### DETAILED DESCRIPTION

A flexible display device is a bendable display device comprising a flexible substrate. Generally, a flexible substrate, such as a layer of polyimide (PI) or polyethylene terephthalate (PET), is formed on a surface of a rigid glass substrate. Then, a plurality of thin-film transistors (TFTs) and a light-emitting layer are formed on the flexible substrate. Finally, the rigid glass substrate is removed by laser lift-off (LLO) or mechanical lift-off (MLO). Because the flexible substrate is thin after peeling off the glass substrate, its stiffness is insufficient, and it is easy to deform, which affects use and service life of the flexible display device. In order to improve strength of the flexible substrate, a support film needs to be adhered below the flexible substrate. The support film is usually a sheet-shaped film made of an organic polymer material and is adhered to the flexible substrate via an optically clear adhesive (OCA) or pressure-sensitive adhesive (PSA).

In a process of adhering the support film, a display module is usually placed upside down on a rigid platform, and then the support film is adhered to a flexible substrate. Then, the support film is rolled with a roller to discharge air bubbles between the support film and the flexible substrate, so that the support film is closely adhered to the flexible substrate. However, a non-display area of a panel has an integrated circuit chip usually made of materials such as silicon (Si), gallium arsenide (GaAs), and silicon carbide (SiC), so it can withstand less pressure. When the non-display area of the panel is locally subjected to stress and the stress exceeds its load limit, it is prone to dangers such as breakage and bump damage. This will affect a circuit performance and then a normal display function of the flexible display device. In addition, because a film structure of the display area and a film structure of the non-display area are different, total thickness of the non-display area is less than total thickness of the display area, resulting in a step difference between the two areas. Therefore, when the support film is adhered, the non-display area cannot be supported by a rigid platform and cannot be rolled by a roller to remove air bubbles between the flexible substrate and the support film. As a result, after the process of adhering support film, air bubbles will exist between the flexible substrate and the support film in the non-display area.

Based on this, the present disclosure provides a display module to solve the aforementioned problem that there are air bubbles between a flexible substrate and a support film in a current display module.

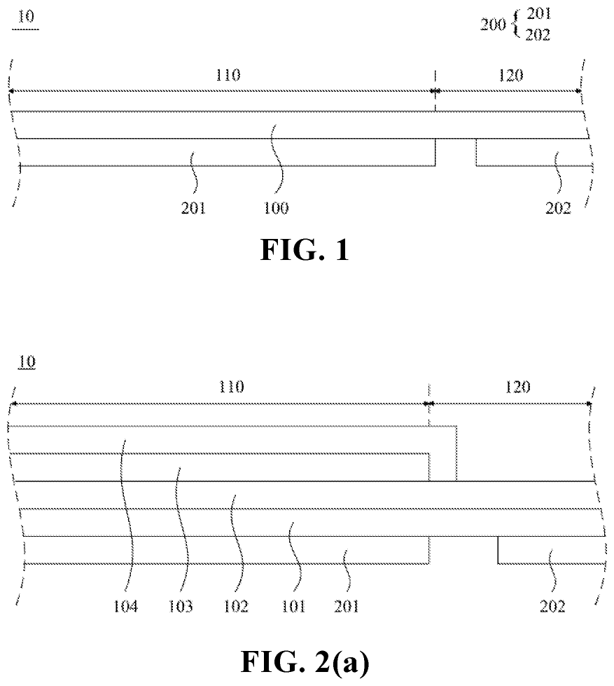

As shown in FIG. 1, the present disclosure provides a display module 10 comprising:
a flexible display panel 100; and
a support film 200 configured to support the flexible display panel 100 and comprising:
   a first support film 201 disposed below a display area 110; and
   a second support film 202 disposed below a non-display area 120 and composed of a cured organic material.

The present disclosure provides a display module, in which a second support film composed of a cured organic material is adhered below a flexible substrate in a non-display area. Because the organic material has good fluidity and adhesiveness, no additional air bubble removal operation is needed. Gas between the flexible substrate and the second support film can be effectively discharged during processes of adhering and curing. This prevents air bubbles from being generated between the flexible substrate and the support film due to a structure of the non-display area.

In an embodiment, the organic material used for the second support film is a hydrogel. A hydrogel is a glue with water as a solvent or dispersant. A hydrogel generally comprises: high-molecular polymers, such as acrylic resin, polyurethane resin, epoxy resin, etc., used to provide strength to the hydrogel; a solvent, i.e., water; a thickener, used to increase viscosity of the hydrogel, provide thixotropy to the hydrogel, and prevent fillers from precipitating; fillers, which have functions of filling, preventing excessive penetration, and improving adhesion force of the hydrogel; and an additive such as a surfactant, a defoamer, a plasticizer, and a bactericide. Curing of a hydrogel is generally irreversible.

Hydrogels are divided into single-component hydrogels and multi-component hydrogels according to their components. With respect to the single-component hydrogels, in some of the single-component hydrogels, adhesive molecules cure after water evaporates. This is a physical process. In some of the single-component hydrogels, as water evaporates, reactive groups of adhesive molecules react to cure the adhesive molecules. This comprises a chemical process and a physical process. With respect to the two-component hydrogels, their curing processes mainly involve chemical processes and are accompanied by physical processes. In an embodiment, the hydrogel used for the second support film may be a single-component hydrogel or multi-component hydrogel, which is not limited herein.

According to type of curing, hydrogels are divided into thermosetting hydrogels and ultraviolet (UV) curable hydrogels. A thermosetting hydrogel is cured by heating it to evaporate its solute. Viscosity of the thermosetting hydrogel can be designed and adjusted according to needs. As curing temperature increases, the viscosity of the thermosetting hydrogel increases. When designed maximum viscosity is reached, the viscosity is stable and no longer changes with increasing temperature. In addition, as the viscosity of the thermosetting hydrogel increases, color of the thermosetting hydrogel becomes darker. During a heating and curing process, viscosity change of the thermosetting hydrogel can be monitored by viscosity change. When the viscosity of the thermosetting hydrogel reaches the designed maximum viscosity, the color of the thermosetting hydrogel will be fixed in the darkest state and no longer change. A UV-curable hydrogel is cured by irradiating ultraviolet light. Viscosity of the UV-curable hydrogel is 500-3000 g/inch and may be determined according to actual needs. The viscosity of the UV-curable hydrogel increases as energy of UV light absorbed by the UV-curable hydrogel increases. The UV-curable hydrogel remains stable after reaching a certain viscosity. Color of the UV-curable hydrogel also becomes darker as the viscosity of the UV-curable hydrogel increases. When the viscosity of UV-curable hydrogel reaches a stable maximum viscosity, the color of the UV-curable hydrogel will remain unchanged. In an embodiment, the hydrogel used for the second support film may be a UV-curable hydrogel or a thermosetting hydrogel, which is not limited herein.

The hydrogel is liquid before it is cured. Water molecules as solvents have excellent wetting and diffusing capabilities. When in contact with a flexible substrate, water molecules can well contact with a surface of the flexible substrate and drive gas away from the surface of the flexible substrate. This ensures that no air bubbles are generated between the flexible substrate and the hydrogel after the hydrogel is cured.

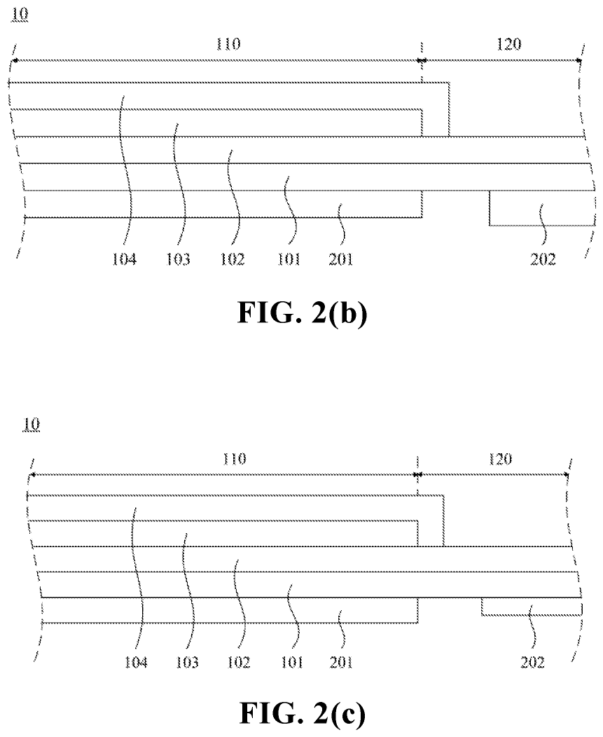

In an embodiment, the display module is an OLED display module. As shown in FIGS. 2(a) to 2(c), the OLED display module 10 comprises a display area 110 and a non-display area 120. In the display area 110, the OLED display module 10 comprises a flexible substrate 101, a TFT layer 102 disposed on the flexible substrate 101, a light-emitting layer 103 disposed on the TFT layer 102, a thin-film encapsulation layer 104 covering the light-emitting layer 103, and a first support film 201 adhered below the flexible substrate. In the non-display area, the OLED display module 10 comprises the flexible substrate 101, the TFT layer 102 disposed on the flexible substrate 101, and a second support film 202 adhered below the flexible substrate 101. There is an interval between the second support film 202 and the first support film 201, and there is no support film in a region of the interval.

In an embodiment, the region of the interval between the second support film 202 and the first support film 201 corresponds to a bending area of the display module. In order to achieve an ultra-narrow frame, an integrated circuit chip (IC) is usually bent to a back of the display module. Therefore, in the bending area of the display module, no support film is provided, and only a flexible substrate and a circuit structure are provided. Thereby, the bending area of the display module is more flexible, and it is easier to bend the integrated circuit chip to the back of the display module to achieve the ultra-narrow frame.

In another embodiment, the region of the interval between the second support film 202 and the first support film 201 corresponds to a fanout area of the display module.

The high-molecular polymers in the hydrogel are round particles, and their radius is generally between 0.5 μm and 5 μm. Adhesion of objects is achieved by attractive force among the high-molecular polymers in the hydrogel. When the water in the hydrogel disappears, the high-molecular polymers in the hydrogel tightly bind the objects together through the attractive force among them. When the hydrogel is over applied, the high-molecular polymers in the hydrogel will crowd together. When the high-molecular polymers are crowded with each other, the strongest attractive force cannot be formed among them. That is, there is no good attractive force among the high-molecular polymers. Further, water among the high-molecular polymers does not easily evaporate. Therefore, thickness of the second support film affects adhesion effect between the second support film and the flexible substrate. If the second support film is too thin or too thick, the adhesion between the second support film and the flexible substrate will be reduced. Therefore, reasonable thickness of the second support film may be designed according to actual panel requirements and the viscosity of the hydrogel.

In an embodiment, as shown in FIG. 2(a), thickness of the second support film 202 is same as thickness of the first support film 201.

In another embodiment, as shown in FIG. 2(b), the thickness of the second support film 202 is greater than the thickness of the first support film 201.

In another embodiment, as shown in FIG. 2(c), the thickness of the second support film 202 is less than the thickness of the first support film 201.

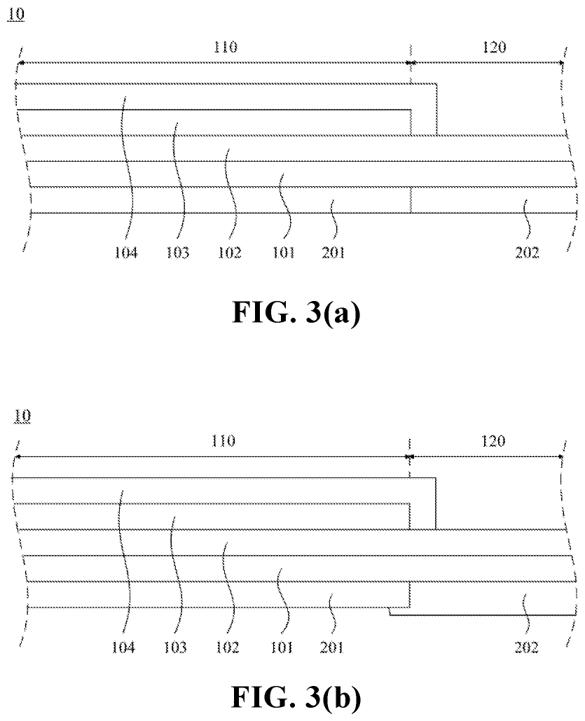

In an embodiment, the display module is an OLED display module. As shown in FIGS. 3(a) to 3(c), the OLED display module 10 comprises a display area 110 and a non-display area 120. In the display area 110, the OLED display module 10 comprises a flexible substrate 101, a TFT layer 102 disposed on the flexible substrate 101, a light-emitting layer 103 disposed on the TFT layer 102, a thin-film encapsulation layer 104 covering the light-emitting layer 103, and a first support film 201 adhered below the flexible substrate 101. In the non-display area, the OLED display module 10 comprises the flexible substrate 101, the TFT layer 102 disposed on the flexible substrate 101, and a second support film 202 adhered below the flexible substrate 101. The first support film 201 is directly connected to the second support film 202.

The second support film 202 is directly connected to the first support film 201. The second support film 202 extends into a bending area of the display module to support and protect the entire non-display area 120 of the display module. Because a hydrogel also has high flexibility after it is cured, it can meet bending requirements of the display module. The second support film 202 and the first support film 201 are connected to each other to prevent a panel of the display module 10 from being damaged during a bending process or other processes due to local absence of the support film.

In an embodiment, as shown in FIG. 3(a), thickness of the second support film 202 is same as thickness of the first support film 201.

In another embodiment, as shown in FIG. 3(b), the thickness of the second support film 202 is greater than the thickness of the first support film 201, and the second support film 202 partially covers the first support film 201. Because the hydrogel is liquid before it is cured, it has excellent fluidity. When the thickness of the second support film is designed to be greater than the thickness of the first support film, the hydrogel as the second support film will inevitably flow to a boundary of the first support film, thereby forming a structure in which the second support film partially covers the first support film.

In another embodiment, as shown in FIG. 3(c), the thickness of the second support film 202 is less than the thickness of the first support film 201.

The present disclosure provides a display device comprising a display module. The display module comprises:
a flexible display panel; and
a support film configured to support the flexible display panel and comprising:
   a first support film disposed below a display area; and
   a second support film disposed below a non-display area and composed of a cured organic material.

The present disclosure provides a flexible display device comprising a display module. The display module comprises a flexible display panel, a first support film disposed in a display area, and a second support film disposed in a non-display area. The second support film is composed of a cured organic material. The second support film composed of the cured organic material is adhered below a flexible substrate in a non-display area. Because the hydrogel has good fluidity and adhesiveness, no additional air bubble removal operation is needed. Gas between the flexible substrate and the second support film can be effectively discharged during processes of adhering and curing. This prevents air bubbles from being generated between the flexible substrate and the support film due to a structure of the non-display area.

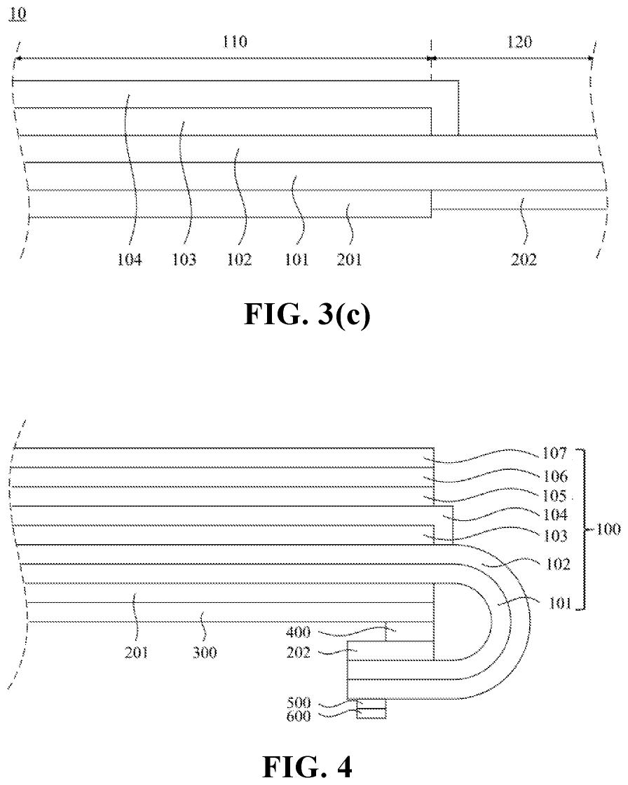

In an embodiment, the flexible display device is a flexible OLED display device. As shown in FIG. 4, the flexible OLED display device comprises:
a flexible display panel 100 comprising a flexible substrate 101, a TFT layer 102 disposed on the flexible substrate 101, a light-emitting layer 103 disposed on the TFT layer 102, a thin-film encapsulation layer 104 covering the light-emitting layer 103, a touch layer 106 disposed on the thin-film encapsulation layer 104, a first optically clear adhesive layer 105 adhering the thin-film encapsulation layer 104 and the touch layer 106, and a polarizer 107 disposed on the touch layer 106;
a first support film 201 and a second support film 202 disposed below the flexible substrate 101, wherein the second support film 202 is composed of a cured organic material;
a copper sheet 300 disposed below the first support film 201 and configured to dissipate heat of the display panel 100;
a reinforcing sheet 400 connected to the first support film 201 and the copper sheet 300;
an anisotropic conductive film 500 disposed on the TFT layer 102; and
an integrated circuit 600 bonded to the TFT layer 102 through the anisotropic conductive film 500.

In an embodiment, the organic material is a hydrogel.

In an embodiment, the hydrogel is a UV-curable hydrogel or a thermosetting hydrogel.

In an embodiment, the hydrogel comprises one or more of acrylic resin, urethane resin, and epoxy resin.

In an embodiment, there is an interval between the second support film 202 and the first support film 201, and there is no support film in a region of the interval. For details, please refer to FIGS. 2(a) to 2(c).

In an embodiment, the region of the interval between the second support film 202 and the first support film 201 corresponds to a bending area of the display module.

In another embodiment, the region of the interval between the second support film 202 and the first support film 201 corresponds to a fanout area of the display module.

In another embodiment, the second support film 202 is directly connected to the first support film 201. For details, please refer to FIGS. 3(a) to 3(c).

In an embodiment, thickness of the second support film 202 is same as thickness of the first support film 201. For details, please refer to FIGS. 2(a) and 3(a).

In an embodiment, the thickness of the second support film 202 is greater than the thickness of the first support film 201. For details, please refer to FIGS. 2(b) and 3(b).

In an embodiment, the thickness of the second support film 202 is less than the thickness of the first support film 201. For details, please refer to FIGS. 2(c) and 3(c).

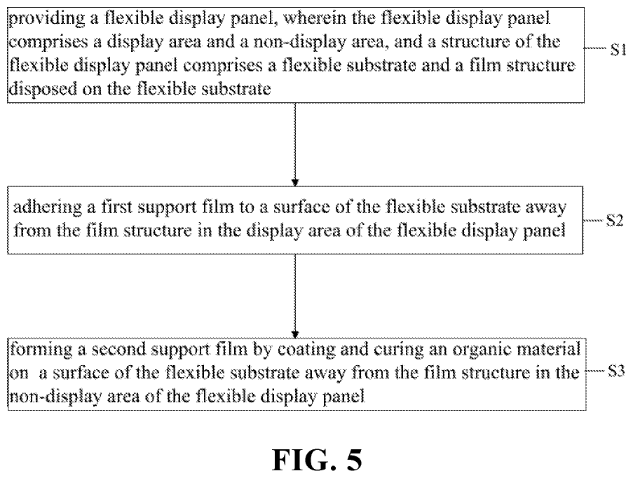

The present disclosure further provides a method for fabricating a display module. As shown in FIG. 5, the method comprises:
S1: providing a flexible display panel;
S2: adhering a first support film to a surface of the flexible substrate away from the film structure in the display area of the flexible display panel; and
S3: adhering a second support film to a surface of the flexible substrate away from the film structure in the non-display area of the flexible display panel.

The present disclosure further provides a method for fabricating a display module. The second support film composed of a hydrogel is adhered to a surface of a flexible substrate away from a functional layer structure in a non-display area. Because the hydrogel has good fluidity and adhesiveness, no additional air bubble removal operation is needed. Gas between the flexible substrate and the second support film can be effectively discharged during processes of adhering and curing. This prevents air bubbles from being generated between the flexible substrate and the support film due to a structure of the non-display area.

In an embodiment, the adhering the first support film to the surface of the flexible substrate away from the film structure in the display area of the flexible display panel comprises the following specific steps.

A mixed layer of polyacetamide and an optically clear adhesive is adhered to the entire surface of the flexible substrate away from the film structure. Specifically, the display module is placed on a rigid support platform. A polyacetamide layer with an optically clear adhesive layer is adhered to the surface of the flexible substrate away from the film structure. Air bubbles between the flexible substrate and the mixed layer of polyacetamide and the optically clear adhesive are rolled out by a roller. In this adhering process, other current adhesion technologies may also be used to complete the adhesion of the flexible substrate and the first support film.

Then, the mixed layer at an interface between the non-display area and the display area is cut by laser or other methods.

The mixed layer disposed on the non-display area is removed.

In an embodiment, the adhering a second support film to a surface of the flexible substrate away from the film structure in the non-display area of the flexible display panel comprises the following specific steps.

A UV-curable hydrogel is coated on the surface of the flexible substrate away from the film structure in a predetermined area of the non-display area. While the UV-curable hydrogel is coated, the UV-curable hydrogel is pre-cured by irradiating ultraviolet light. Pre-curing is to change the UV-curable hydrogel from liquid to semi-solid to prevent the UV-curable hydrogel from flowing, and its curing degree is about 20%.

The pre-cured UV-curable hydrogel is completely cured to form a completely cured second support film.

In another embodiment, the adhering a second support film to a surface of the flexible substrate away from the film structure in the non-display area of the flexible display panel comprises the following specific steps.

A thermosetting hydrogel is coated on the surface of the flexible substrate away from the film structure in a predetermined area of the non-display area. While the thermosetting hydrogel is coated, the thermosetting hydrogel is pre-cured by heating. Pre-curing is to change the thermosetting hydrogel from liquid to semi-solid to prevent the thermosetting from flowing, and its curing degree is about 20%.

The pre-cured thermosetting hydrogel is completely cured to form a completely cured second support film.

The present disclosure provides a display module, a method for fabricating the same, and a display panel comprising the same. The display module comprises a flexible display panel, a first support film disposed in a display area, and a second support film disposed in a non-display area. The second support film is composed of a cured organic material. The second support film composed of the cured organic material is adhered below a flexible substrate in a non-display area. Because the organic material has good fluidity and adhesiveness, no additional air bubble removal operation is needed. Gas between the flexible substrate and the second support film can be effectively discharged during processes of adhering and curing. This prevents air bubbles from being generated between the flexible substrate and the support film due to a structure of the non-display area. Furthermore, a color of a hydrogel changes according to a viscosity of the hydrogel. This property can be used to determine and control whether the viscosity of the hydrogel conforms to a design, so as to prepare a second support film with a high yield and reduce a risk of the second support film peeling off from the flexible substrate.

The present disclosure has been described in the above preferred embodiments, but the preferred embodiments are not intended to limit the scope of the present disclosure, and those skilled in the art may make various modifications without departing from the scope of the present disclosure. The scope of the present disclosure is determined by claims.

1. A display module, comprising:
a flexible display panel comprising a display area and a non-display area; and
a support film configured to support the flexible display panel and comprising:
a first support film disposed below the display area; and
a second support film disposed below the non-display area and composed of a cured organic material.

2. The display module according to claim 1, wherein the organic material is a hydrogel.

3. The display module according to claim 2, wherein the hydrogel is a UV-curable hydrogel or a thermosetting hydrogel.

4. The display module according to claim 2, wherein the hydrogel comprises one or more of acrylic resin, urethane resin, and epoxy resin.

5. The display module according to claim 1, wherein the second support film is directly connected to the first support film.

6. The display module according to claim 1, wherein there is an interval between the second support film and the first support film, and there is no support film in a region of the interval.

7. The display module according to claim 6, wherein the region of the interval corresponds to a bending area of the flexible display panel.

8. The display module according to claim 1, wherein thickness of the second support film is less than thickness of the first support film.

9. The display module according to claim 1, wherein thickness of the second support film is a same as thickness of the first support film.

10. The display module according to claim 1, wherein thickness of the second support film is greater than thickness of the first support film.

11. A display device, comprising a display module, wherein the display module comprises:
a flexible display panel comprising a display area and a non-display area; and
a support film configured to support the flexible display panel and comprising:
a first support film disposed below the display area; and
a second support film disposed below the non-display area and composed of a cured organic material.

12. The display device according to claim 11, wherein the organic material is a hydrogel.

13. The display device according to claim 12, wherein the hydrogel is a UV-curable hydrogel or a thermosetting hydrogel.

14. The display device according to claim 12, wherein the hydrogel comprises one or more of acrylic resin, urethane resin, and epoxy resin.

15. The display device according to claim 11, wherein the second support film is directly connected to the first support film.

16. The display device according to claim 11, wherein there is an interval between the second support film and the first support film, and there is no support film in a region of the interval.

17. The display device according to claim 16, wherein the region of the interval corresponds to a bending area of the flexible display panel.

18. The display device according to claim 11, wherein thickness of the second support film is less than thickness of the first support film.

19. The display device according to claim 11, wherein thickness of the second support film is a same as thickness of the first support film.

20. A method for fabricating a display module, comprising:
providing a flexible display panel, wherein the flexible display panel comprises a display area and a non-display area, and a structure of the flexible display panel comprises a flexible substrate and a film structure disposed on the flexible substrate;
adhering a first support film to a surface of the flexible substrate away from the film structure in the display area of the flexible display panel; and
forming a second support film by coating and curing an organic material on a surface of the flexible substrate away from the film structure in the non-display area of the flexible display panel.
